(19) United States
(12) Patent Application Publication
(10) Pub. No.: US 2025/0310075 A1
(43) Pub. Date: Oct. 2, 2025

(54) Multi-Channel Synchronous Acquisition and Transmission System Based on JESD204B Protocol

(71) Applicant: Jiangsu Huachuang Microsystem Company Limited, Nanjing (CN)

(72) Inventors: Pengfei KONG, Nanjing (CN); Yong QI, Nanjing (CN); Tao ZHANG, Nanjing (CN); Guoqiang HE, Nanjing (CN)

(73) Assignee: Jiangsu Huachuang Microsystem Company Limited, Nanjing (CN)

(21) Appl. No.: 19/004,521

(22) Filed: Dec. 30, 2024

(30) Foreign Application Priority Data
Mar. 26, 2024 (CN) 202410350905.5

(51) Int. Cl. H04L 7/00; G01S 13/42

(52) U.S. Cl. CPC H04L 7/0016; G01S 13/426

(57) ABSTRACT

A multi-channel synchronous acquisition and transmission system based on the JESD204B protocol includes a multi-channel AD synchronous acquisition module, a signal source module, a power module and an upper computer module, wherein the signal source module sends a reference clock and multiple analog signals to the multi-channel AD synchronous acquisition module; the multi-channel AD synchronous acquisition module includes an FPGA, a multi-channel ADC, an independent clock source and multiple devices; the independent clock source receives the reference clock and transmits a sysref signal; a time window is configured in the multi-channel ADC; the FPGA generates a sync signal and synthesizes an LMFC, and an edge of the sysref signal is taken as an edge of the LMFC; in the multi-channel ADC, a corresponding ILAS is set for each digital signal; and the FPGA receives all the ILASs and digital signals, and multiple digital signals are processed synchronously.

### CROSS REFERENCE TO THE RELATED APPLICATIONS

This application is based upon and claims priority to Chinese Patent Application No. 202410350905.5, filed on Mar. 26, 2024, the entire contents of which are incorporated herein by reference.

### TECHNICAL FIELD

The invention relates to the technical field of high-speed serial interface chips, in particular to a multi-channel synchronous acquisition and transmission system based on the JESD204B protocol.

### BACKGROUND

The phased array technology, since its appearance, greatly improves the capacity of radars because of its quick beam scanning, flexibility and spatial filtering and orienting capacity. Early phased array radars adopt three classic channels which are respectively a sum channel, an azimuth channel and a pitch channel, and use a large quantity of phase shifters, attenuators, sum-difference devices and other analog devices. A multi-channel phased array radar includes multiple antenna subarray, radio-frequency and signal processing channels, and uses more digital techniques. The use of multiple channels greatly improves the degree of freedom of a system. Based on software-defined radio, digital processing is performed preferentially to allow a radar system to support adaptive beamforming, spatial spectrum estimation, spatial-temporal adaptive signal processing, and other advanced spatial processing algorithms, such that the performance of the system is greatly improved.

At present, many research institutions carried out research and development of key technologies and systems of multi-channel phased array radars. The use of multiple channels does not merely indicate an increase in the number of channels and is accompanied by the difficulty in guaranteeing the consistency of multiple channels after the sampling rate and data transmission rate of one channel are increased, leading to a degradation of system performance. In fact, synchronization is a key problem that must be solved for all multi-channel phased array radars.

With the progress of technology, the analog-to-digital (AD) and digital-to-analog (DA) sampling rate has reached gigabit per second. However, traditional parallel devices cannot satisfy the engineering requirements for multiple channels and miniaturization because they have a limited sampling rate and use too many pins. To solve such a conflict, the Joint Electron Device Engineering Council (JEDEC) issued the JESD204B protocol, which simplifies system design, reduces power consumption, supports synchronization between channels and increases the transmission rate to 12.5 Gbps by means of serial data links and common-mode logic levels, thus having a broad application prospect.

However, in phased array transmission based on the JESD204B protocol, it is difficult to realize multi-channel synchronization between multiple clock chips and analog-to-digital converter (ADCs), and large delays and errors are often generated between different signals corresponding to multiple channels, making performance and indicators fail to satisfy actual requirements.

### SUMMARY

The technical issue to be settled by the invention is how to design an operating mode for different signals transmitted in multiple channels and how to restrain the delay time of different signals to realize synchronization of multiple clocks and ADCs so as to effectively reduce delays and errors.

To settle the above technical issue, the invention provides a multi-channel synchronous acquisition and transmission system based on the JESD204B protocol; which is implemented by the following technical solution:

A multi-channel synchronous acquisition and transmission system based on the JESD204B protocol, including a multi-channel AD synchronous acquisition module, a signal source module, a power module and an upper computer module; the power module supplying power to the multi-channel AD synchronous acquisition module, the upper computer module being connected to the multi-channel AD synchronous acquisition module by means of a network cable, and the signal source module transmitting multiple analog signals to the multi-channel AD synchronous acquisition module:
the signal source module at least includes a signal source 1 and a signal source 2, the signal source 1 sends a reference clock to the multi-channel AD synchronous acquisition module, the signal source 2 sends multiple analog signals to the multi-channel AD synchronous acquisition module, and each analog signal corresponds to a channel; the multi-channel AD synchronous acquisition module at least includes a field-programmable gate array (FPGA), a multi-channel analog-to-digital converter (ADC), an independent clock source and multiple devices in conformity with a subclass1 standard;
wherein, every two of the independent clock source, the multi-channel ADC and the FPGA are connected by means of multiple JESD204B interfaces; the independent clock source receives the reference clock sent from the signal source 1 and transmits a sysref signal to the multi-channel ADC and the FPGA based on the reference clock; a time window is configured in the multi-channel ADC, and an edge of the sysref signal received by the multi-channel ADC is controlled to fall within the time window; the FPGA generates a sync signal, a local multi-frame clock (LMFC) is synthesized by the sync signal and the sysref signal received by the FPGA, and the edge of the sysref signal received by the FPGA is taken as an edge of the LMFC; a corresponding initial lane alignment sequence (ILAS) is set for each digital signal in the multi-channel ADC, and the multi-channel ADC sends each ILAS and the corresponding digital signal to the FPGA according to the LMFC;
after receiving all the ILASs and all the corresponding digital signals, the FPGA synchronously processes all the digital signals with a next nearest edge of the LMFC as a starting point, such that multi-channel synchronous acquisition and transmission are realized.

A time window is configured, the edge of a sysref signal received by a multi-channel ADC is strictly controlled, and each signal and clock are transmitted at a same starting point by means of a LMFC synthesized by an FPGA, such that the transmission delay is strictly controlled; in addition, after receiving all ILASs and signals to be processed, the FPGA synchronously processes the ILASs and signals, thus further guaranteeing the synchronization of data and effectively reducing delays and errors.

Preferably, an odelay resources and an Xilinx analog-to-digital converter (XADC) are configured in the FPGA; in case of a change of an ambient temperature, a delay caused by the change of the ambient temperature is set as odelay, and a specific value of the odelay is determined by means of the odelay resources and the XADC, and the digital signals are synchronously corrected in the FPGA according to the specific value of the odelay. Because the change of temperature will lead to a change of the delay in the transmission process, odelay resources are configured in the FPGA to ensure that a delay and an error caused by the change of temperature are within a specified range.

Preferably, the FPGA reads a core temperature of the FPGA from the XADC and establishes a lookup table; and the specific value of the odelay is determined according to the lookup table, and a transmission process of the system is corrected by means of the odelay resources. By means of data in a lookup table, the specific value of an odelay can be quickly determined, and then a transmission delay is corrected according to the specific value.

Preferably, a register is configured in the FPGA, and a delay-related reliable region is saved in the register; in case of a change of the ambient temperature, a method for determining the specific value of the odelay includes: sending multiple sysref signals to the FPGA by the independent clock source, establishing, in the FPGA, an odelay set value for each sysref signal, reading the reliable region in the register to determine a specific odelay set value, located in the reliable region, in the multiple odelay set values, and taking the specific odelay set value as the specific value of the odelay. Multiple sysref test signals are sent, and the specific value of the odelay can be determined from multiple odelay set values, such that a delay caused by the change of temperature can be corrected.

Preferably, wherein before the multi-channel ADC sends each ILAS and the corresponding digital signal to the FPGA, the FPGA first pulls down the sync signal and transmits a K28.5 code to the multi-channel ADC, and then pulls up the sync signal to allow the multi-channel ADC to send each ILAS and the corresponding digital signal to the FPGA with a next valid clock in the LMFC as a starting point. A sync signal can be pulled down and up to clearly indicate the current logic state of the FPGA, thus ensuring the clarity and reliability of subsequent operations.

Preferably, a buffer is configured in the FPGA; and before the FPGA receives all ILASs and all corresponding digital signals, each ILAS and the corresponding digital signal received by the FPGA are buffered in the buffer. The FPGA may receive different ILASs at different times and may receive different digital signals at different times, so buffer is configured to buffer the ILASs and the digital signals, and after all data are received, these data are processed synchronously, thus realizing synchronous multi-channel data processing.

Preferably, an AD sampling clock is configured in the multi-channel ADC, and the AD sampling clock is kept as long as the independent clock source. An AD sampling clock is kept as long as an independent clock source to strictly keep the transmission speed of a multi-channel AD synchronous acquisition module constant, and the two clock sources correspond to two key signals respectively and thus should be strictly as long as each other to reduce a routing delay.

Preferably, the power module is a direct current (DC) voltage-stabilized source. A DC voltage-stabilized source is used to ensure the power supply stability, and it will not generate noise like an alternating current (AC) power supply, such that the stability and accuracy of multi-channel synchronous acquisition and transmission are guaranteed to the maximum extent.

Preferably, the signal source 1 is an arbitrary waveform generator. An arbitrary waveform generator has the characteristics of high accuracy, stability and flexibility and can provide desired high-accuracy clock signals, thus guaranteeing the accuracy of clock data.

Compared with the prior art, the invention has the following beneficial effects:

According to the technical solution of the invention, the FPGA and the multi-channel ADC take the sysref signal as the edge of the LMFC, the time for AD sampling is kept as long as the independent clock source, and multiple signals and the phases and periods of different clocks are strictly controlled to be synchronous, such that transmission and sampling delays can be minimized; in addition, the buffer is configured in the FPGA, such that data corresponding to multiple channels can be aligned to be processed synchronously, and errors and delays caused by processing before all data are received are effectively avoided; moreover, odelay resources are configured in the FPGA, and errors or delays caused by the change of temperature can be effectively handled.

### BRIEF DESCRIPTION OF THE DRAWINGS

FIG. 1 is a schematic diagram of a multi-channel synchronous acquisition and transmission system based on the JESD204B protocol;

FIG. 2 is a comparison chart of waveforms and phases of signals in four channels;

FIG. 3 is an expanded comparison chart of waveforms and phases of signals in four channels.

### DETAILED DESCRIPTION OF THE EMBODIMENTS

The technical solutions in some embodiments of the invention are described in detail below in conjunction with drawings of these embodiments.

### Embodiment

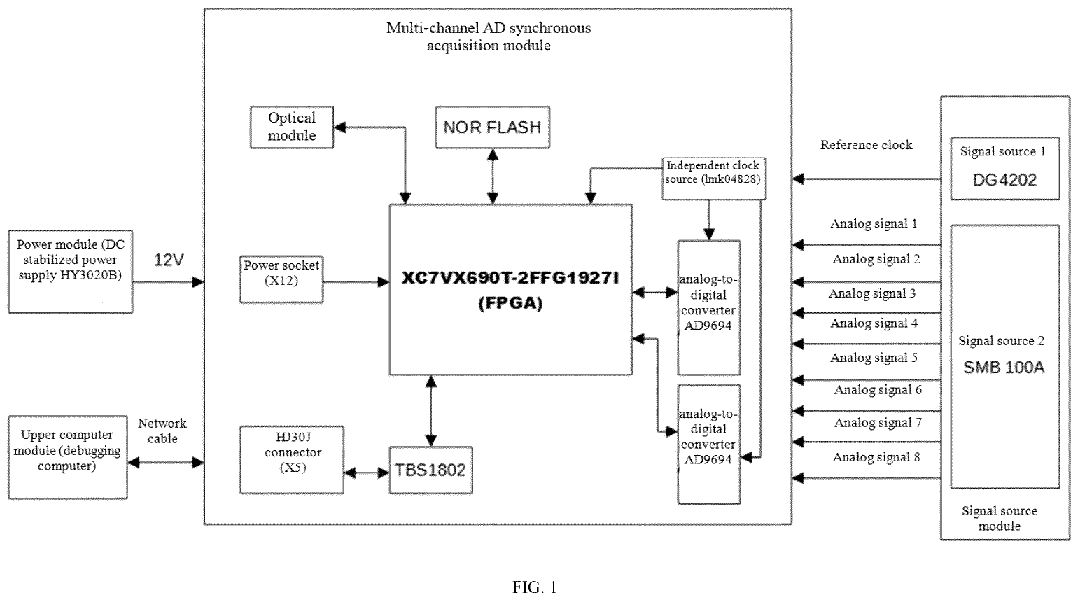

As shown in FIG. 1 which is a schematic diagram of a multi-channel synchronous acquisition and transmission system based on the JESD204B protocol, a multi-channel AD synchronous acquisition module receives multiple analog signals transmitted from a signal source module, the analog signals are converted by an ADC into digital signals, and the digital signals are sent to a field programmable gate array (FPGA) to be processed synchronously.

The multi-channel synchronous acquisition and transmission system based on the JESD204B protocol is formed by four modules: a power module, an upper computer module, a multi-channel AD synchronous acquisition module and a signal source module. The power module is used for stably supplying power to the multi-channel AD synchronous acquisition module. The upper computer module is connected to the multi-channel AD synchronous acquisition module by means of a network cable and used for debugging. The signal source module includes a signal source 1 and a signal source 2, wherein the signal source 1 provides a reference clock for the multi-channel AD synchronous acquisition module, and the signal source 2 sends multiple analog signals to the multi-channel AD synchronous acquisition module.

The power module may be a DC voltage-stabilized source and can stably supply power to the multi-channel AD synchronous acquisition module with low noise. The use of an AC power supply will undoubtedly exert an influence on acquisition and transmission, leading to a larger delay or error. The upper computer module may be a debugging computer and can simply and efficiently make an adjustment to a transmission process and operations to be executed. The signal source 1 of the signal source module may be an arbitrary waveform generator, which has the characteristics of high accuracy, operability, flexibility and stability, and can generate desired custom waveforms to satisfy reference clock design requirements, and even if the waveform and phase of the reference clock are improper, they can be edited and modified quickly; and the signal source 2 may be a radio frequency generator that can provide multiple analog signals. The multi-channel AD synchronous acquisition module is provided with an FPGA, a multi-channel ADC, an independent clock source and multiple devices in conformity with the subclass1 standard, and the FPGA, the multi-channel AD synchronous acquisition module and the independent clock source are all provided with JESD204B interfaces, which are used for connection between every two of the FPGA, the multi-channel AD synchronous acquisition module and the independent clock source.

It should be noted that the subclass1 standard is an interface standard for connecting and managing different devices and is a protocol implemented for IEEE 1394 interfaces, and it allows for communication between digital devices under a high bandwidth and a low delay and is conformity with the JESD204B interface standard.

In this embodiment, the multiple devices in conformity with the subclass1 standard in the multi-channel AD synchronous acquisition module include a power socket, a network connector, an isolation drive chip and a flash memory. The power socket is connected to the power module and used for supplying power to the FPGA and other devices to be powered. One terminal of the network connector is connected to the upper computer module, the other terminal of the network connector is connected to the isolation drive chip, and the isolation drive chip is connected to the FPGA, such that the FPGA and the upper computer module are connected to realize debugging in a test. The flash memory may be NOR FLASH, connected to the FPGA and mainly used for storing program codes and data required by the FPGA, and the NOR FLASH has an extremely high read rate and a low delay and can satisfy the requirement for a low delay of this scheme. In addition, in addition to the above five devices, other devices may be added as actually needed in an actual test and design as long as the added devices are in conformity with the subclass1 standard. In addition, an indicator light may be configured in the multi-channel AD synchronous acquisition module, and the indicator light is connected to the FPGA to be turned on/off for indication when the FPGA performs some operations.

In this embodiment, the FPGA in the multi-channel AD synchronous acquisition module may be connected to an optical module, and the optical module can realize conversion between optical signals and electrical signals and used for data transmission between the FPGA and other external devices. The optical module has the advantages of high speed, remote transmission and high anti-interference capacity and is suitable for scenarios requiring high-speed data transmission and data integrity.

In this embodiment, the signal source 2 sends multiple analog signals to the multi-channel ADC, and each analog signal occupies a channel and corresponds to an initial lane alignment sequence (ILAS); in addition, the signal source 1 sends a reference clock to the independent clock source, and the dependent clock source generates a sysref signal based on the reference clock and sends the sysref signal to the FPGA and the multi-channel ADC.

The multi-channel ADC receives the multiple analog signals and the sysref signal, performs AD sampling to convert each analog signal into a digital signal, and sends each digital signal and the corresponding ILAS to the FPGA. The number of channels of the multi-channel ADC should be greater than or equal to the number of the analog signals. If the channels of the multi-channel ADC are not sufficient, more multi-channel ADCs may be configured to ensure that all the analog signals can be received.

At the beginning of acquisition and transmission of the system, the FPGA will be reset, at this moment, a sync signal is generated, and the sysref signal is taken as a starting position of an edge of the sync signal; the FPGA synthesizes the sync signal and the sysref signal to obtain a local multi-frame clock (LMFC) and an edge of the LMFC, and the sysref signal is also a starting position of the edge of the LMFC; and in the multi-channel ADC, AD sampling is performed on each analog signal, and the sysref signal is also taken as a starting position of an edge of a clock used for AD sampling. In this way, by controlling the starting positions, synchronization between signals and clocks is guaranteed, and the consistency in waveform, phase and period is realized, thus effectively reducing the delay.

It should be noted that the edge of a clock refers to a rising edge or a falling edge of a clock signal. The clock signal is a signal that changes periodically, and is used for realizing synchronization and controlling various operations in a digital system. The edge is a time or boundary at which the clock signal changes from one status to another status. By unified control of the edges of multiple signals, the occurrence of an event can be triggered, data sampling and transmission can be controlled, and synchronous operations can be realized, thus ensuring that data of multiple signals are read, written or processed at a correct time; and particularly in the FPGA, operations of internal logic circuits are synchronized by detecting the edges of clock signals, thus guaranteeing correct transmission and processing of data.

In this embodiment, a time window may be set in the multi-channel ADC according to the position of the edge of an AD clock, the time window characterizes a setup time and a hold time, and whether the sysref signal falls within the time window can be monitored to further ensure that the AD clock is as along as the sysref signal.

In this embodiment, when the multi-channel ADC sends each ILAC and the corresponding digital signal to the FPGA, a new delay and error may be generated if the FPGA starts to receive these data at different times. In view of this, a buffer may be configured in the FPGA to buffer data received by the FPGA, and after all the ILASs and all the digital signals are saved in the buffer, the FPGA processes the ILASs and the digital signals synchronously to align data of all channels, thus realizing a certain delay.

In this embodiment, odelay sources and a Xilinx analog-to-digital convert (XADC) may be configured in the FPGA to avoid a delay and an error caused by a change of the ambient temperature. The odelay sources, also referred to as output delay resources, allow users to accurately control delays of output signals of the FPGA and are suitable for scenarios requiring accurate synchronization and timing control. The XADC is an ADC in the FPGA.

In case of a change of the ambient temperature, a routing delay (the transmission speed of electrical signals) is affected by the dielectric constant; when the ambient temperature changes within 20° C.-80° C., the dielectric constant changes within 3%, and if the influence on the delay is within a permissible range, it can be ignored. However, with the increase of the change of the ambient temperature, the influence on the delay will be greater, may finally become an important influence factor of the transmission path delay in the FPGA, and will also affect the setup of the sysref signal, and a measure must be taken at this moment. The delay caused by the change of the temperature is an odelay. The FPGA reads a core temperature from the XADC and establishes a lookup table, and a specific value of the odelay is determined according to data in the lookup table, such that all the digital signals transmitted by the multi-channel ADC can be synchronously corrected by means of the odelay sources. In addition, a register for saving data is configured in the FPGA, the register includes a reliable region related to the odelay, multiple odelay set values are assumed for the odelay, the sysref signal is sent repeatedly by the independent clock source, the register in the FPGA is read in case of each odelay set value to determine whether the corresponding odelay set value falls within the reliable region, the odelay set value that falls within the reliable region is determined after multiple tests and is taken as the specific value of the odelay, and then, delay correction is performed according to the specific value to guarantee the validity and accuracy of transmission.

### Specific Application Example:

A multi-channel synchronous acquisition and transmission system based on the JESD204B protocol is configured on a printed circuit board (PCB) and formed by a DC voltage-stabilized source HY3020B, a debugging computer, a multi-channel AD synchronous acquisition module, a signal source DG4202 (an arbitrary waveform generator) and a signal source SMB100A (radio frequency generator). The multi-channel AD synchronous acquisition module includes a power socket, an HJ30J connector, an isolation drive chip TBS1802, an FPGA (XC7VX690T-2FFG1927I), a NOR FLASH, an independent clock source (lmk04828), two AD9694 ADCs and an optical module.

The power socket is an X12 power socket, and the DC voltage-stabilized source HY3020B supplies 12V power to the FPGA by means of the power socket; the debugging computer is connected to one terminal of the X5 HJ30J connector by means of a network cable, the other terminal of the HJ30J connector is connected to an isolation drive chip TBS1802, and the isolation drive chip TBS1802 is connected to the FPGA. The FPGA is provided with three JESD204B interfaces, each AD9694 ADC is provided with a JESD204B interface, and the independent clock source is provided with three JESD204B interfaces. The NOR FLASH is connected to the FPGA and stores program codes and data required by the FPGA.

When the multi-channel acquisition and transmission system starts to operate, the signal source SMB100A sends eight analog signals to the two AD9694 ADCs, one AD9694 ADC receives analog signals 1-4, the other AD9694 ADC receives analog signals 5-8, and the two AD9694 ADCs are connected in parallel and synchronous. When the signal source SMB100A sends the analog signals, the signal source DG4202 sends a reference clock to lmk04828, and lmk04828 generates a sysref signal based on the reference clock and sends the reference signal to the FPGA and the two AD9694 ADCs.

The FPGA is reset and generates a sync signal with the sysref signal as an edge, an LMFC is synthesized by means of the sync signal and the sysref signal, edge information of the LMFC is obtained, and the LMFC also takes the sysref signal as an edge, thus ensuring the consistency in phase, frequency and other features of the multiple signals.

AD sampling is performed in the two AD9694 ADCs respectively, at this moment, a time window is configured on the edge of the AD clock, and the sysref signal is monitored by means of the time window to ensure that a clock used for AD sampling also takes the sysref signal as an edge. After AD sampling is ended, the eight analog signals are converted into eight digital signals and eight corresponding ILASs; and the two AD9694 ADCs send the eight digital signals and the eight corresponding ILASs to the FPGA.

When the FPGA successively receives the digital signals and the ILASs, all these received data are stored in a buffer to be buffered; and when the eight digital signals and the eight corresponding ILASs are all stored in the buffer, the FPGA invokes a program in the NOR FLASH and synchronously processes these data with a next nearest edge of the LMFC as a starting point.

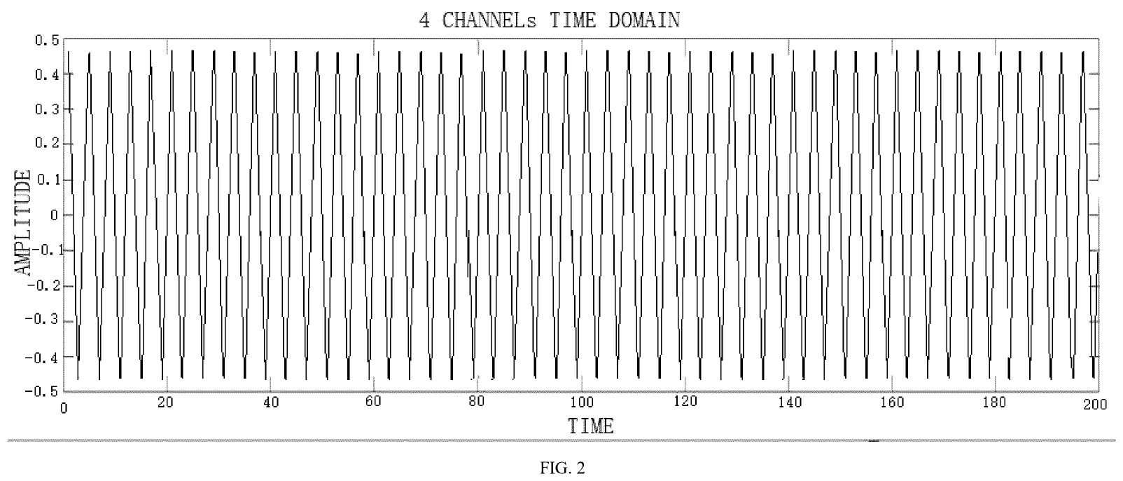

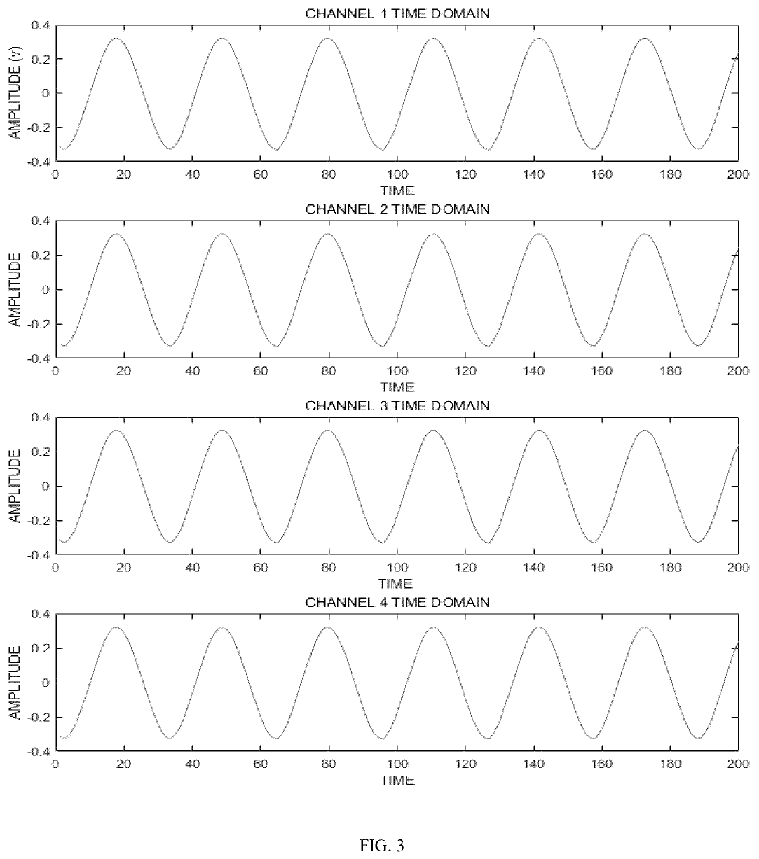

Then, the debugging computer establishes data connection with the FPGA by means of the network cable, the HJ30J connector and the isolation drive chip TBS1802 to obtain all the data received by the FPGA, and phase differences between different signals are calculated by means of data processing software MATLAB and VIVADO in the debugging computer. FIG. 2 is a comparison diagram of phases and waveforms of four digital signals converted from the analog signals 1-4, wherein TIME indicates time, 4 CHANNELS TIME DOMAIN indicates the time domain of four signals, and AMPLITUDE indicates the amplitude. It can be seen from FIG. 2 that the phases and waveforms of the four signals almost coincide. FIG. 3 is an expanded comparison chart of waveforms and phases of four digital signals converted from the analog signals 5-8, wherein CHANNEL 1 TIME DOMAIN indicates an expanded waveform of the digital signal corresponding to the analog signal 5, CHANNEL 2 TIME DOMAIN indicates an expanded waveform of the digital signal corresponding to the analog signal 6, CHANNEL 3 TIME DOMAIN indicates an expanded waveform of the digital signal corresponding to the analog signal 7, and CHANNEL 4 TIME DOMAIN indicates an expanded waveform of the digital signal corresponding to the analog signal 8. It can be seen from FIG. 3 that the expanded waveforms of the four signals are almost the same, indicating that signal alignment and synchronization are completed, multi-channel synchronous acquisition and transmission are realized, the accuracy is high, and the delay is low.

After low-delay synchronous acquisition and transmission are realized, the optical module receives the eight digital signals to be transmitted and related data from the FPGA and coverts these signals and data into an electrical signal, and the electrical signal is sent from a transmission position in the optical module to an external device, such that output to the outside is completed.

After the transmission system operates normally for a period of time, the dielectric constant of the PCB actually used by the transmission system will be greatly affected due to heat generated in the transmission system and a change of the ambient temperature, leading to an odelay that cannot be ignored in the transmission process. At this moment, the FPGA reads a core temperature from an XADC in the FPGA, establishes a lookup table according to the core temperature, and compares current delay data with data obtained in a previous normal transmission process according to the lookup table to determine a specific value of the current odelay. Then, the digital signals transmitted by the AD9694 ADCs are synchronously corrected by means of odelay sources in the FPGA to further reduce the delay, such that low-delay multi-channel synchronous transmission is realized.

In the invention, the FPGA and the multi-channel ADC take the sysref signal as the edge of the LMFC, the time for AD sampling is kept as long as the independent clock source, and multiple signals and the phases and periods of different clocks are strictly controlled to be synchronous, such that transmission and sampling delays can be minimized; in addition, the buffer is configured in the FPGA, such that data corresponding to multiple channels can be aligned to be processed synchronously, and errors and delays caused by processing before all data are received are effectively avoided; moreover, the odelay resources are configured in the FPGA, and errors or delays caused by the change of temperature can be effectively handled, such that a remarkable improvement is achieved.

The above embodiments are merely used for explaining the technical concept of the invention and are not intended to limit the protection scope of the invention. Any modifications made based on the technical concept of the invention should also fall within the protection scope of the invention.

What is claimed is:

1. A multi-channel synchronous acquisition and transmission system based on a JESD204B protocol, comprising a multi-channel analog-to-digital (AD) synchronous acquisition module, a power module, an upper computer module and a signal source module, wherein the power module supplies power to the multi-channel AD synchronous acquisition module, the upper computer module is connected to the multi-channel AD synchronous acquisition module by a network cable, and the signal source module transmits a plurality of analog signals to the multi-channel AD synchronous acquisition module, wherein:
the signal source module at least comprises a first signal source and a second signal source, wherein the first signal source sends a reference clock to the multi-channel AD synchronous acquisition module, the second signal source sends the plurality of analog signals to the multi-channel AD synchronous acquisition module, and each analog signal corresponds to a channel; the multi-channel AD synchronous acquisition module at least comprises a field-programmable gate array (FPGA), a multi-channel analog-to-digital converter (ADC), an independent clock source and a plurality of devices in conformity with a subclass1 standard;
wherein, every two of the independent clock source, the multi-channel ADC and the FPGA are connected by a plurality of JESD204B interfaces; the independent clock source receives the reference clock sent from the first signal source and transmits a sysref signal to the multi-channel ADC and the FPGA based on the reference clock; a time window is configured in the multi-channel ADC, and an edge of the sysref signal received by the multi-channel ADC is controlled to fall within the time window; the FPGA generates a sync signal, a local multi-frame clock (LMFC) is synthesized by the sync signal and the sysref signal received by the FPGA, and the edge of the sysref signal received by the FPGA is taken as an edge of the LMFC; a corresponding initial lane alignment sequence (ILAS) is set for each digital signal in the multi-channel ADC, and the multi-channel ADC sends each ILAS and the corresponding digital signal to the FPGA according to the LMFC; and
after receiving all the ILASs and all the corresponding digital signals, the FPGA synchronously processes all the digital signals with a next nearest edge of the LMFC as a starting point, such that multi-channel synchronous acquisition and transmission are realized.

2. The multi-channel synchronous acquisition and transmission system based on the JESD204B protocol according to claim 1, wherein odelay resources and an Xilinx analog-to-digital converter (XADC) are configured in the FPGA; in case of a change of an ambient temperature, a delay caused by the change of the ambient temperature is set as odelay, a specific value of the odelay is determined by the odelay resources and the XADC, and the digital signals are synchronously corrected in the FPGA according to the specific value of the odelay.

3. The multi-channel synchronous acquisition and transmission system based on the JESD204B protocol according to claim 2, wherein the FPGA reads a core temperature of the FPGA from the XADC and establishes a lookup table; and the specific value of the odelay is determined according to the lookup table, and a transmission process of the multi-channel synchronous acquisition and transmission system is corrected by the odelay resources.

4. The multi-channel synchronous acquisition and transmission system based on the JESD204B protocol according to claim 2, wherein a register is configured in the FPGA, and a delay-related reliable region is saved in the register; in case of a change of the ambient temperature, a method for determining the specific value of the odelay comprises: sending a plurality of sysref signals to the FPGA by the independent clock source, establishing, in the FPGA, an odelay set value for each sysref signal, reading the delay-related reliable region in the register to determine a specific odelay set value, located in the delay-related reliable region, in a plurality of odelay set values, and taking the specific odelay set value as the specific value of the odelay.

5. The multi-channel synchronous acquisition and transmission system based on the JESD204B protocol according to claim 1, wherein before the multi-channel ADC sends each ILAS and the corresponding digital signal to the FPGA, the FPGA first pulls down the sync signal and transmits a K28.5 code to the multi-channel ADC, and then pulls up the sync signal to allow the multi-channel ADC to send each ILAS and the corresponding digital signal to the FPGA with a next valid clock in the LMFC as a starting point.

6. The multi-channel synchronous acquisition and transmission system based on the JESD204B protocol according to claim 1, wherein a buffer is configured in the FPGA; and before the FPGA receives all ILASs and all corresponding digital signals, each ILAS and the corresponding digital signal received by the FPGA are buffered in the buffer.

7. The multi-channel synchronous acquisition and transmission system based on the JESD204B protocol according to claim 1, wherein an AD sampling clock is configured in the multi-channel ADC, and the AD sampling clock is kept as long as the independent clock source.

8. The multi-channel synchronous acquisition and transmission system based on the JESD204B protocol according to claim 1, wherein the power module is a direct current (DC) voltage-stabilized source.

9. The multi-channel synchronous acquisition and transmission system based on the JESD204B protocol according to claim 1, wherein the first signal source is an arbitrary waveform generator.
